(19) United States
(12) Patent Application Publication
(10) Pub. No.: US 2026/0258546 A1
(43) Pub. Date: Sep. 3, 2026

(54) PRECURSORS AND METHODS FOR DEPOSITING METAL-CONTAINING FILMS

(71) Applicant: ENTEGRIS, INC., Billerica, MA (US)

(72) Inventors: Claudia Fafard, New Milford, CT (US); Thomas M. Cameron, Newtown, CT (US); Bryan C. Hendrix, Danbury, CT (US)

(21) Appl. No.: 19/551,538

(22) Filed: Feb. 26, 2026

Related U.S. Application Data
(60) Provisional application No. 63/765,311, filed on Feb. 28, 2025.

(51) Int. Cl. C23C 16/14; C09K 13/00; C23C 16/455

(52) U.S. Cl. CPC C23C 16/14; C09K 13/00; C23C 16/45553

(57) ABSTRACT

Precursors and methods for depositing metal-containing films are provided herein. The method includes obtaining a substrate comprising a plurality of halides. The method includes obtaining a reducing agent. The method includes contacting the substrate with the reducing agent to remove at least a portion of the plurality of halides. Related compositions and articles are also provided.

### FIELD

The present disclosure relates to precursors and methods for depositing metal-containing films.

### BACKGROUND

Metal containing films are useful in the manufacturing of microelectronic devices.

### SUMMARY

Some embodiments relate to a method. In some embodiments, the method comprises obtaining a substrate. In some embodiments, the substrate comprises a plurality of halides. In some embodiments, the method comprises obtaining a reducing agent. In some embodiments, the reducing agent comprises a compound of the formula:

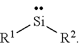

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring. In some embodiments, the method comprises contacting the substrate with the reducing agent to at least remove at least a portion of the plurality of halides.

Some embodiments relate to a kit. In some embodiments, the kit comprises a first container. In some embodiments, the first container comprises a vaporizable precursor. In some embodiments, the vaporizable precursor comprises a metal halide. In some embodiments, the kit comprises a second container. In some embodiments, the second container comprises a reducing agent. In some embodiments, the reducing agent comprises a compound of the formula:

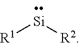

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring. In some embodiments, when the vaporizable precursor and the reducing agent are vaporized and contacted with a substrate comprising at least one of a plurality of halides, a plurality of silylenes, or any combination thereof, the vaporizable precursor and the reducing agent react to form a film on the substrate.

Some embodiments relate to an article. In some embodiments, the article comprises a film. In some embodiments, the film comprises a reaction product of a reducing agent and a metal halide. In some embodiments, the reducing agent comprises a compound of the formula:

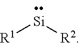

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring. In some embodiments, the film comprises less than 10% by weight of a halide based on a total weight of the film.

Some embodiments relate to an article. In some embodiments, the article comprises a film. In some embodiments, the film comprises a reaction product of a silylene and a metal halide. In some embodiments, the film comprises less than 10% by weight of a halide based on a total weight of the film.

Some embodiments relate to a composition. In some embodiments, the composition comprises a reducing agent for film deposition. In some embodiments, the reducing agent comprises a compound of the formula:

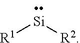

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring.

### BRIEF DESCRIPTION OF THE DRAWINGS

FIG. 1 is a flowchart of a method for forming a film, according to some embodiments.

FIG. 2 is a flowchart of a method for forming a film, according to some embodiments.

FIG. 3 is an illustration of a method for forming a film, according to some embodiments.

FIG. 4 is an illustration of a method for forming a film, according to some embodiments.

### DETAILED DESCRIPTION

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 2 to 30 carbon atoms and at least one carbon-carbon double bond. In some embodiments, the alkenyl comprises or is selected from the group consisting of at least one of a C₂-C₃₀ alkenyl, C₂-C₂₉ alkenyl, C₂-C₂₈ alkenyl, C₂-C₂₇ alkenyl, C₂-C₂₇ alkenyl, C₂-C₂₆ alkenyl, C₂-C₂₅ alkenyl, C₂-C₂₄ alkenyl, C₂-C₂₃ alkenyl, C₂-C₂₂ alkenyl, C₂-C₂₁ alkenyl, C₂-C₂₀ alkenyl, C₂-C₁₉ alkenyl, C₂-C₁₈ alkenyl, C₂-C₁₇ alkenyl, C₂-C₁₆ alkenyl, C₂-C₁₅ alkenyl, C₂-C₁₄ alkenyl, C₂-C₁₃ alkenyl, C₂-C₁₂ alkenyl, C₂-C₁₁ alkenyl, C₂-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₂-C₄ alkenyl, a C₂-C₃ alkenyl, a C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 2 to 30 carbon atoms and at least one carbon-carbon triple bond. In some embodiments, the alkynyl comprises or is selected from the group consisting of at least one of a C₂-C₃₀ alkynyl, C₂-C₂₉ alkynyl, C₂-C₂₈ alkynyl, C₂-C₂₇ alkynyl, C₂-C₂₇ alkynyl, C₂-C₂₆ alkynyl, C₂-C₂₅ alkynyl, C₂-C₂₄ alkynyl, C₂-C₂₃ alkynyl, C₂-C₂₂ alkynyl, C₂-C₂₁ alkynyl, C₂-C₂₀ alkynyl, C₂-C₁₉ alkynyl, C₂-C₁₈ alkynyl, C₂-C₁₇ alkynyl, C₂-C₁₆ alkynyl, C₂-C₁₅ alkynyl, C₂-C₁₄ alkynyl, C₂-C₁₃ alkynyl, C₂-C₁₂ alkynyl, C₂-C₁₁ alkynyl, C₂-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₂-C₄ alkynyl, a C₂-C₃ alkynyl, a C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “heterocycloalkyl” refers to a cycloalkyl, as defined herein, wherein at least one of the carbon atoms in the ring is replaced with at least one of a nitrogen atom, a sulfur atom, an oxygen atom, a phosphorous atom, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

Non-limiting examples of aryls include, without limitation, at least one of phenyl, tolyl, xylyl (e.g., o-xylyl, m-xylyl, p-xylyl), t-butyltolyl, (e.g., o-t-butyltolyl, m-t-butyltolyl, p-t-butyltolyl), ethylmethylphenyl (e.g., 1-ethyl-4-methylphenyl, 1-ethyl-3-methylphenyl), 1-isopropyl-4-methylphenyl, 1-t-butyl-4-methylphenyl, mesitylene, pseudocumene, durene, methylphenyl, dimethylphenyl, trimethylphenyl, ethylphenyl, diethylphenyl (e.g., 1,4-diethylphenyl), triethylphenyl, propylphenyl, butylphenyl, iso-butylphenyl, sec-butylphenyl, t-butylphenyl, hexylphenyl, styrene, naphthyl, anthracenyl, phenanthrene, biphenyl, terphenyl, methylnaphthyl, biphenylene, dimethylnaphthyl, methylanthracenyl, 4,4′-dimethylbiphenyl, diphenylmethane, any isomer thereof, or any combination thereof, and the like.

As used herein, the term “heteroaryl” refers to an aryl, as defined herein, wherein at least one of the carbon atoms in the ring is replaced with at least one of a nitrogen atom, a sulfur atom, an oxygen atom, a phosphorous atom, or any combination thereof.

As used herein, the term “amino” and/or “amine” refers to a functional group of formula —N(R^{a}R^{b}), wherein R^{a} and R^{b} are independently a hydrogen, an alkyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of amine containing compounds included alkylamines. Examples of the alkylamines may include, without limitation, one or more of the following: primary alkylamines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary alkylamines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary alkylamines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris (2-aminoethyl)amine, tetra (aminomethyl) methane, diethylenetriamine, triethylenetetramine, tetraethylpentamine, heptaethyleneoctamine, nonaethylenedecamine, and diazabicyloundecene. Unless otherwise provided herein, the terms “amine” and “amino” may be used interchangeably throughout this disclosure.

As used herein, the term “halide” refers to a —Cl, —Br, —I, or —F.

As used herein, the term “metal” refers to at least one of an alkali metal, an alkaline earth metal, a transition metal, a post-transition metal, or any combination thereof. In some embodiments, the metal comprises a metal cation. In some embodiments, the metal cation comprises at least one of a lithium cation, a sodium cation, a potassium cation, a rubidium cation, a cesium cation, a magnesium cation, a calcium cation, a strontium cation, a barium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, a tin cation, a lead cation, a bismuth cation, a polonium cation, a lanthanum cation, a germanium cation, or any combination thereof. The charge(s) of the metal cations are known and, for simplicity, thus are not repeated here; however, it will be appreciated that the metal cations can have any known charge.

Some embodiments relate to precursors and related methods. At least some of these embodiments relate to precursors useful in the fabrication of microelectronic devices, including semiconductor devices, and the like. In some embodiments, a precursor comprising a metal halide is deposited on a substrate. In some embodiments, a reducing agent is subsequently deposited on the substrate. In some embodiments, the reducing agent reacts with the precursor to form a high purity film on the substrate. In some embodiments, the film comprises at least one of a metal, a plurality of silylenes, or any combination thereof. In some embodiments, a precursor comprising a metal halide is deposited on a substrate comprising a plurality of silylenes. In some embodiments, the precursor reacts with the silylenes to form a high purity film on the substrate. In some embodiments, the film comprises at least one of a metal, a metal silicide, or any combination thereof.

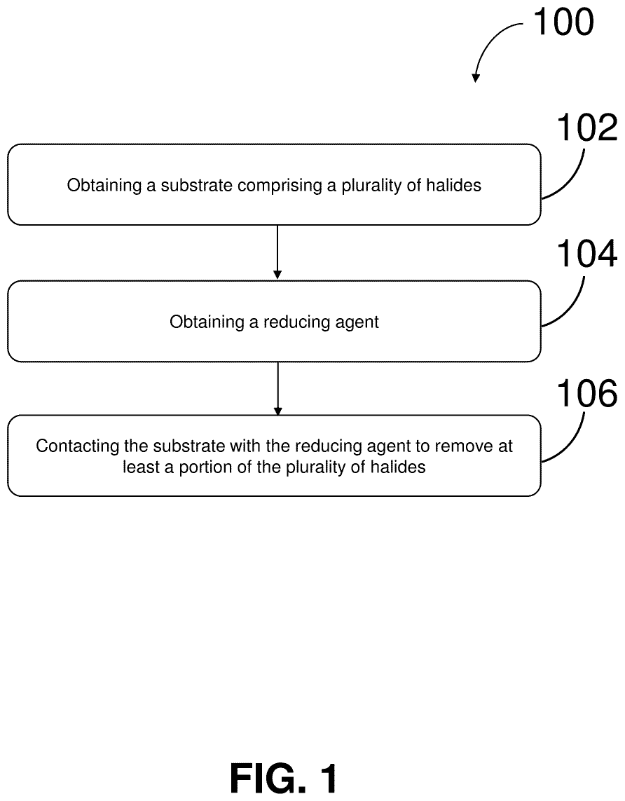

FIG. 1 is a flowchart of a method for making a film 100, according to some embodiments. As shown in FIG. 1, the method of making a film 100 may comprises any one or more of the following steps: obtaining 102 a substrate comprising a plurality of halides, obtaining 104 a reducing agent, and contacting 106 the substrate with the reducing agent to remove at least a portion of the plurality of halides.

At step 102, in some embodiments, the method comprises obtaining a substrate comprising a plurality of halides. The substrate may comprise at least one of Si, Ge, Co, Cu, Al, W, WN, WC, TIN, Mo, MOC, SiO₂, W, SiN, WCN, Al₂O₃, AlN, ZrO₂, La₂O₃, TaN, RuO₂, IrO₂, Nb₂O₃, Y₂O₃, hafnium oxide, a metal, or any combination thereof. In some embodiments, the plurality of halides is located on a surface of the substrate. In some embodiments, the plurality of halides comprises at least one of a silicon halide, a germanium halide, a metal halide, or any combination thereof. In some embodiments, the metal halide comprises at least one of an alkali metal halide, an alkaline metal halide, a rare earth metal halide, a transition metal halide, a post-transition metal halide, or any combination thereof. In some embodiments, the metal halide comprises at least one of a scandium halide, a yttrium halide, a lanthanum halide, a zirconium halide, a titanium halide, a hafnium halide, a niobium halide, a tantalum halide, an aluminum halide, a vanadium halide, a molybdenum halide, a tungsten halide, or any combination thereof.

In some embodiments, the obtaining comprises obtaining a substrate and contacting the substrate, under vapor deposition conditions, with a vaporized precursor to obtain a substrate with a plurality of halides. In some embodiments, the vaporized precursor comprises a metal halide. The contacting may be performed in any system, apparatus, device, assembly, chamber thereof, or component thereof suitable for vapor deposition processes, including, for example and without limitation, a deposition chamber, among others.

In some embodiments, the step of obtaining comprises vaporizing the precursor to obtain a vaporized precursor. The vaporizing may comprise heating the precursor sufficient to obtain the vaporized precursor. In some embodiments, the vaporizing comprises heating a container comprising the precursor. In some embodiments, the vaporizing comprises heating a conduit for delivering the precursor, the vaporized precursor, or any combination thereof to, for example, a deposition chamber. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof.

In some embodiments, the step of obtaining comprises exposing, under vapor deposition conditions, a substrate to the vaporized precursor to form a substrate with a plurality of halides. The exposing may be performed in any system, apparatus, device, assembly, chamber thereof, or component thereof suitable for vapor deposition processes, including, for example and without limitation, a deposition chamber, among others. In some embodiments, the exposing comprises contacting the substrate with at least the vaporized precursor.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the vaporized precursor. The deposition temperature may be sufficiently high to reduce or avoid condensation of the vaporized precursor. In some embodiments, the substrate may be heated to the deposition temperature. In some embodiments, the chamber or other vessel in which the substrate is contacted with the vaporized precursor is heated to the deposition temperature. In some embodiments, the vaporized precursor may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of the vaporized precursor. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 m Torr to 100 m Torr, 1 m Torr to 90 m Torr, 1 mTorr to 80 m Torr, 1 m Torr to 70 m Torr, 1 m Torr to 60 m Torr, 1 mTorr to 50 mTorr, 1 mTorr to 40 mTorr, 1 m Torr to 30 mTorr, 1 m Torr to 20 m Torr, 1 m Torr to 10 m Torr, 100 m Torr to 300 m Torr, 150 m Torr to 300 m Torr, 200 m Torr to 300 m Torr, or 150 m Torr to 250 m Torr, or 150 m Torr to 225 m Torr.

At step 104, in some embodiments, the method comprises obtaining a reducing agent. In some embodiments, the obtaining comprises obtaining the reducing agent in the form of a liquid. In some embodiments, the obtaining comprises obtaining the reducing agent in the form of a solid. In some embodiments, the obtaining comprises obtaining the reducing agent in the form of a vapor. In some embodiments, the obtaining comprises obtaining a vessel comprising the reducing agent. In some embodiments, the obtaining comprises obtaining a container comprising the reducing agent.

In some embodiments, the reducing agent comprises a silylene. In some embodiments, the reducing agent comprises a compound of the formula:

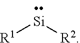

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring. In some embodiments, R¹ and R² are different. In some embodiments, R¹ and R² are the same. In some embodiments, when R¹ and R² are bonded to form a cyclic ring, the number of atoms between R¹ and R² is 1 to 10, or any range or subrange between 1 to 10. In some embodiments, when R¹ and R² are bonded to form a cyclic ring, the number of atoms between R¹ and R² is 1 to 9, 1 to 8, 1 to 7, 1 to 6, 1 to 5, 1 to 4, 1 to 3, 1 to 2, 2 to 10, 3 to 10, 4 to 10, 5 to 10, 6 to 10, 7 to 10, 8 to 10, or 9 to 10. In some embodiments, when R¹ and R² are bonded to form a cyclic ring, the atoms between R¹ and R² comprise at least one of carbon atoms, nitrogen atoms, sulfur atoms, oxygen atoms, phosphorous atoms, or any combination thereof.

In some embodiments, the reducing agent comprises a compound of the formula:

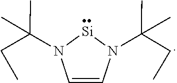

In some embodiments, the step of obtaining comprises vaporizing the reducing agent to obtain a vaporized reducing agent. The vaporizing may comprise heating the reducing agent sufficient to obtain the vaporized reducing agent. In some embodiments, the vaporizing comprises heating a container comprising the reducing agent. In some embodiments, the vaporizing comprises heating the reducing agent in a deposition chamber in which the vapor deposition process is performed. In some embodiments, the vaporizing comprises heating a conduit for delivering the reducing agent, the vaporized reducing agent, or any combination thereof to, for example, a deposition chamber. In some embodiments, the vaporizing comprises operating a vapor delivery system comprising the reducing agent. In some embodiments, the vaporizing comprises heating to a temperature sufficient to vaporize the reducing agent to obtain the vaporized reducing agent. In some embodiments, the vaporizing comprises heating to a temperature below a decomposition temperature of the reducing agent.

At step 106, in some embodiments, the method comprises contacting the substrate with the reducing agent to remove at least a portion of the plurality of halides. In some embodiments, the contacting comprises flowing the reducing agent across the substrate. In some embodiments, the contacting comprises dipping the substrate in the reducing agent. In some embodiments, the contacting comprises submerging the substrate in the reducing agent. In some embodiments, the contacting comprises placing the substrate in a vessel comprising the reducing agent. In some embodiments, the contacting comprising placing the reducing agent in a vessel comprising the substrate.

In some embodiments, the contacting comprises exposing the substrate, under vapor deposition conditions, to the vaporized reducing agent to remove at least a portion of the plurality of halides. The exposing may be performed in any system, apparatus, device, assembly, chamber thereof, or component thereof suitable for vapor deposition processes, including, for example and without limitation, a deposition chamber, among others.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the reducing agent. The deposition temperature may be sufficiently high to reduce or avoid condensation of the reducing agent. In some embodiments, the substrate may be heated to the deposition temperature. In some embodiments, the chamber or other vessel in which the substrate is contacted with the reducing agent is heated to the deposition temperature. In some embodiments, the reducing agent may be heated to the deposition temperature.

The deposition temperature may be a temperature of 200° C. to 2000° C., or any range or subrange between 200° C. and 2000° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2000° C., such as, for example and without limitation, a temperature of 300° C. to 2000° C., 400° C. to 2000° C., 500° C. to 2000° C., 550° C. to 2000° C., 600° C. to 2000° C., 625° C. to 2000° C., 650° C. to 2000° C., 675° C. to 2000° C., 700° C. to 2000° C., 725° C. to 2000° C., 750° C. to 2000° C., 775° C. to 2000° C., 800° C. to 2000° C., 825° C. to 2000° C., 850° C. to 2000° C., 875° C. to 2000° C., 900° C. to 2000° C., 925° C. to 2000° C., 950° C. to 2000° C., 975° C. to 2000° C., 1000° C. to 2000° C., 1025° C. to 2000° C., 1050° C. to 2000° C., 1075° C. to 2000° C., 1100° C. to 2000° C., 1200° C. to 2000° C., 1300° C. to 2000° C., 1400° C. to 2000° C., 1500° C. to 2000° C., 1600° C. to 2000° C., 1700° C. to 2000° C., 1800° C. to 2000° C., 1900° C. to 2000° C., 200° C. to 1900° C., 200° C. to 1800° C., 200° C. to 1700° C., 200° C. to 1600° C., 200° C. to 1500° C., 200° C. to 1400° C., 200° C. to 1300° C., 200° C. to 1200° C., 200° C. to 1100° C., 200° C. to 1000° C., 200° C. to 1000° C., 200° C. to 900° C., 200° C. to 800° C., 200° C. to 700° C., 200° C. to 600° C., 200° C. to 500° C., 200° C. to 400° C., or 200° C. to 300° C.

The vapor deposition conditions may comprise a deposition pressure. In some embodiments, the deposition pressure may comprise a vapor pressure of the reducing agent. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 m Torr to 100 m Torr, 1 m Torr to 90 m Torr, 1 m Torr to 80 m Torr, 1 m Torr to 70 mTorr, 1 m Torr to 60 mTorr, 1 mTorr to 50 mTorr, 1 mTorr to 40 mTorr, 1 mTorr to 30 mTorr, 1 m Torr to 20 m Torr, 1 m Torr to 10 m Torr, 100 m Torr to 300 m Torr, 150 m Torr to 300 m Torr, 200 m Torr to 300 m Torr, or 150 mTorr to 250 mTorr, or 150 m Torr to 225 m Torr.

In some embodiments, the precursor and the reducing agent are vaporized simultaneously. In some embodiments, the precursor is vaporized and subsequently, the reducing agent is vaporized. In some embodiments, the precursor and the reducing agent are vaporized together. In some embodiments, the precursor and the reducing agent are vaporized separately.

In some embodiments, the precursor and the reducing agent are contacted with the substrate simultaneously. In some embodiments, the precursor and the reducing agent may be alternately and/or sequentially contacted, in one or more cycles, with the substrate.

In some embodiments, contacting the substrate with the reducing agent removes at least 10% by weight of the plurality of halides based on a total weight of the plurality of halides. In some embodiments, contacting the substrate with the reducing agent removes at least 20%, at least 30%, at least 35%, at least 40%, at least 45%, at least 50%, at least 55%, at least 60%, at least 65%, at least 70%, at least 75%, at least 80%, at least 85%, at least 90%, or at least 95% by weight of the plurality of halides based on a total weight of the plurality of halides.

In some embodiments, contacting the substrate with the reducing agent removes 10% to 100%, or any range or subrange between 10% to 100%, by weight of the plurality of halides based on a total weight of the plurality of halides. In some embodiments, contacting the substrate with the reducing agent removes 10% to 95%, 10% to 90%, 10% to 85%, 10% to 80%, 10% to 75%, 10% to 70%, 10% to 65%, 10% to 60%, 10% to 55%, 10% to 45%, 10% to 40%, 10% to 35%, 10% to 30%, 10% to 25%, 10% to 20%, 10% to 15%, 15% to 100%, 20% to 100%, 25% to 100%, 30% to 100%, 35% to 100%, 40% to 100%, 45% to 100%, 50% to 100%, 55% to 100%, 60% to 100%, 65% to 100%, 70% to 100%, 75% to 100%, 80% to 100%, 85% to 100%, 90% to 100%, or 95% to 100% by weight of the plurality of halides based on the total weight of the halides.

In some embodiments, removing at least a portion of the plurality of halides results in a film. In some embodiments, the film comprises less than 10% by weight of a halide based on a total weight of the film. In some embodiments, the film comprises less than 9%, less than 8%, less than 7%, less than 6%, less than 5%, less than 4%, less than 3%, less than 2%, less than 1%, less than 0.5%, or less than 0.1% by weight of a halide based on the total weight of the film.

In some embodiments, the film comprises 0.01% to 10%, or any range or subrange between 0.01% to 10%, by weight of a halide based on the total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a halide based on a total weight of the film. In some embodiments, the film does not comprise a halide.

In some embodiments, the amount of any one or more components of a film are measured by at least one of x-ray fluorescence (XRF), x-ray photoelectron spectroscopy (XPS), or secondary ion mass spectrometry (SIMS). In some embodiments, the amount of any one or more components of a film are measured by XRF. In some embodiments, the amount of any one or more components of a film are measured by XPS. In some embodiments, the amount of any one or more components of a film are measured by SIMS.

In some embodiments, the film comprises at least one of a metal, a plurality of silylenes, or any combination thereof. In some embodiments, the metal comprises at least one of an alkali metal, an alkaline earth metal, a rare earth metal, a transition metal, a post-transition metal, or any combination thereof. In some embodiments, the metal comprises at least one of a scandium, a yttrium, a lanthanum, a zirconium, a titanium, a hafnium, a vanadium, a niobium, a tantalum, an aluminum, a molybdenum, a tungsten or any combination thereof. In some embodiments, the plurality of silylenes is in the form of metal silylenes.

In some embodiments, the film comprises at least 90% by weight of at least one of a metal, a plurality of silylenes, or any combination thereof, based on the total weight of the film. In some embodiments, the film comprises at least 91%, at least 92%, at least 93%, at least 94%, at least 95%, at least 96%, at least 97%, at least 98%, at least 99%, at least 99.5%, at least 99.9%, at least 99.95%, or at least 99.99% by weight of at least one of a metal, a plurality of silylenes, or any combination thereof, based on the total weight of the film.

In some embodiments, the film comprises 90% to 99.99%, or any range or subrange between 90% to 99.99%, by weight of at least one of a metal, a plurality of silylenes, or any combination thereof, based on a total weight of the film. In some embodiments, the film comprises 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99% by weight of at least one of a metal, a plurality of silylenes, or any combination thereof, based on a total weight of the film.

In some embodiments, the film comprises less than 10% by weight of a carbon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a carbon based on a total weight of the film.

In some embodiments, the film comprises 0.01% to 10%, or any range or subrange between 0.01% to 10%, by weight of a carbon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a carbon based on a total weight of the film.

In some embodiments, the film comprises less than 10% by weight of a silicon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a silicon based on a total weight of the film.

In some embodiments, the film comprises 0.01% to 10%, or any range or subrange between 0.01% to 10%, by weight of a silicon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a silicon based on a total weight of the film.

In some embodiments, the film comprises less than 10% by weight of a nitrogen based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a nitrogen based on a total weight of the film.

In some embodiments, the film comprises 0.01% to 10%, or any range or subrange between 0.01% to 10%, by weight of a nitrogen based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a nitrogen based on a total weight of the film.

In some embodiments, the film comprises a metal film. In some embodiments, the method comprises contacting the metal film with a metal halide. In some embodiments, contacting the metal film with a metal halide results in a substrate comprising a plurality of halides. In some embodiments, the contacting comprises any one or more of the contacting methods disclosed herein.

In some embodiments, completing steps 102, 104, and 106 completes one cycle. In some embodiments, the cycle is restarted by contacting the metal film obtained in step 106 with a metal halide to obtain a substrate comprising a plurality of halides. In some embodiments, one or more cycles are performed. In some embodiments, multiple cycles are performed. For example, in some embodiments, at least 1 cycle, at least 5 cycles, at least 10 cycles, at least 50 cycles, at least 100 cycles, at least 500 cycles, or at least 1000 cycles are performed. In some embodiments, 1 to 1000 cycles, or any range or subrange between 1 to 1000 cycles, are performed. In some embodiments, 1 to 900 cycles, 1 to 800 cycles, 1 to 700 cycles, 1 to 600 cycles, 1 to 500 cycles, 1 to 400 cycles, 1 to 300 cycles, 1 to 200 cycles, 1 to 100 cycles, 1 to 50 cycles, 1 to 10 cycles, 10 to 1000 cycles, 50 to 1000 cycles, 100 to 1000 cycles, 200 to 1000 cycles, 300 to 1000 cycles, 400 to 1000 cycles, 500 to 1000 cycles, 600 to 1000 cycles, 700 to 100 cycles, 800 to 1000 cycles, or 900 to 1000 cycles are performed. In some embodiments, the number of cycles performed are determined by the desired thickness of the resulting film.

In some embodiments, the number of cycles performed are sufficient to result in a metal film having a thickness of 5 Å to 5000 Å, or any range or subrange between 5 Å to 5000 Å. In some embodiments, the metal film has a thickness of 5 Å to 4500 Å, 5 Å to 4000 Å, 5 Å to 3500 Å, 5 Å to 3000 Å, 5 Å to 2500 Å, 5 Å to 2000 Å, 5 Å to 1500 Å, 5 Å to 1000 Å, 5 Å to 500 Å, 5 Å to 100 Å, 5 Å to 50 Å, 50 Å to 5000 Å, 100 Å to 5000 Å, 500 Å to 5000 Å, 1000 Å to 5000 Å, 1500 Å to 5000 Å, 2000 Å to 5000 Å, 2500 Å to 5000 Å, 3000 Å to 5000 Å, 3000 Å to 5000 Å, 3500 Å to 5000 Å, 4000 Å to 5000 Å, or 4500 Å to 5000 Å.

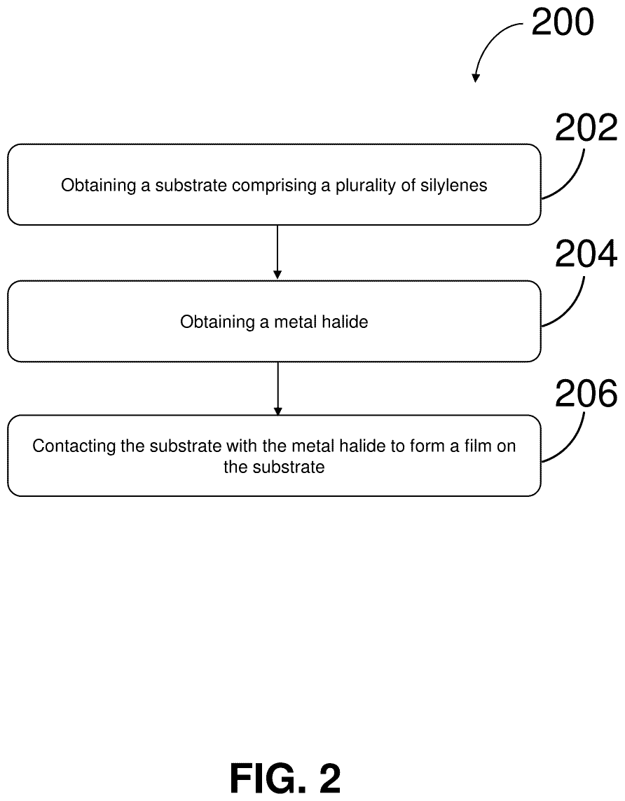

FIG. 2 is a flowchart of a method for making a film 200, according to some embodiments. As shown in FIG. 2, the method of making a film 200 may comprises any one or more of the following steps: obtaining 202 a substrate comprising a plurality of silylenes, obtaining 204 a metal halide, and contacting 206 the substrate with the metal halide to form a film on the substrate.

At step 202, in some embodiments, the method comprises obtaining a substrate comprising a plurality of silylenes. In some embodiments, the substrate comprising a plurality of silylenes is obtained by method 100 as shown in FIG. 1.

At step 204, in some embodiments, the method comprises obtaining a metal halide. The metal halide may comprise any one or more metal halides disclosed herein. In some embodiments, the obtaining comprises obtaining the metal halide in the form of a liquid. In some embodiments, the obtaining comprises obtaining the metal halide in the form of a solid. In some embodiments, the obtaining comprises obtaining the metal halide in the form of a vapor. In some embodiments, the obtaining comprises obtaining a vessel comprising the metal halide. In some embodiments, the obtaining comprises obtaining a container comprising the metal halide.

In some embodiments, the obtaining step comprises vaporizing the metal halide to obtain a vaporized metal halide. The vaporizing may comprise heating the metal halide sufficient to obtain the vaporized metal halide. In some embodiments, the vaporizing comprises heating a container comprising the metal halide. In some embodiments, the vaporizing comprises heating the metal halide in a deposition chamber in which the vapor deposition process is performed. In some embodiments, the vaporizing comprises heating a conduit for delivering the metal halide, the vaporized metal halide, or any combination thereof to, for example, a deposition chamber. In some embodiments, the vaporizing comprises operating a vapor delivery system comprising the metal halide. In some embodiments, the vaporizing comprises heating to a temperature sufficient to vaporize the metal halide to obtain the vaporized metal halide. In some embodiments, the vaporizing comprises heating to a temperature below a decomposition temperature of the metal halide.

At step 206, in some embodiments, the method comprises contacting the substrate with the metal halide to form a film on the substrate. In some embodiments, the contacting comprises flowing the metal halide across the substrate. In some embodiments, the contacting comprises dipping the substrate in the metal halide. In some embodiments, the contacting comprises submerging the substrate in the metal halide. In some embodiments, the contacting comprises placing the substrate in a vessel comprising the metal halide. In some embodiments, the contacting comprising placing the metal halide in a vessel comprising the substrate.

In some embodiments, the contacting comprises exposing the substrate, under vapor deposition conditions, to the vaporized metal halide to form a film on the substrate. The exposing may be performed in any system, apparatus, device, assembly, chamber thereof, or component thereof suitable for vapor deposition processes, including, for example and without limitation, a deposition chamber, among others.

The vapor deposition conditions may comprise any one or more vapor deposition conditions disclosed herein. The vapor deposition process may any one or more vapor deposition processes disclosed herein.

In some embodiments, the film formed on the substrate comprises at least one of a metal, a metal silicide, or any combination thereof. In some embodiments, the metal comprises at least one of an alkali metal, an alkaline earth metal, a rare earth metal, a transition metal, a post-transition metal, or any combination thereof. In some embodiments, the metal comprises at least one of a scandium, a yttrium, a lanthanum, a zirconium, a titanium, a hafnium, a vanadium, a niobium, a tantalum, an aluminum, a vanadium, a tantalum, a molybdenum, a tungsten or any combination thereof.

In some embodiments, the film comprises at least 90% by weight of at least one of a metal, a metal silicide, or any combination thereof, based on the total weight of the film. In some embodiments, the film comprises at least 91%, at least 92%, at least 93%, at least 94%, at least 95%, at least 96%, at least 97%, at least 98%, at least 99%, at least 99.5%, at least 99.9%, at least 99.95%, or at least 99.99% by weight of at least one of a metal, a metal silicide, or any combination thereof, based on the total weight of the film.

In some embodiments, the film comprises 90% to 99.99%, or any range or subrange between 90% to 99.99%, by weight of at least one of a metal, a metal silicide, or any combination thereof, based on a total weight of the film. In some embodiments, the film comprises 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99% by weight of at least one of a metal, a metal silicide, or any combination thereof, based on a total weight of the film.

In some embodiments, the film comprises less than 10% by weight of a halide based on a total weight of the film. In some embodiments, the film comprises less than 9%, less than 8%, less than 7%, less than 6%, less than 5%, less than 4%, less than 3%, less than 2%, less than 1%, less than 0.5%, or less than 0.1% by weight of a halide based on the total weight of the film.

In some embodiments, the film comprises 0.01% to 10%, or any range or subrange between 0.01% to 10%, by weight of a halide based on the total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a halide based on a total weight of the film. In some embodiments, the film does not comprise a halide.

In some embodiments, the film comprises less than 10% by weight of a carbon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a carbon based on a total weight of the film.

In some embodiments, the film comprises 0.01% to 10%, or any range or subrange between 0.01% to 10%, by weight of a carbon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a carbon based on a total weight of the film.

In some embodiments, the film comprises less than 10% by weight of a silicon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a silicon based on a total weight of the film.

In some embodiments, the film comprises 0.01% to 10%, or any range or subrange between 0.01% to 10%, by weight of a silicon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a silicon based on a total weight of the film.

In some embodiments, the film comprises less than 10% by weight of a nitrogen based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a nitrogen based on a total weight of the film.

In some embodiments, the film comprises 0.01% to 10%, or any range or subrange between 0.01% to 10%, by weight of a nitrogen based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a nitrogen based on a total weight of the film.

In some embodiments, the film comprises at least one of a metal film, a metal silicide film, or any combination thereof. In some embodiments, the method comprises contacting the film with a metal halide. In some embodiments, contacting the film with a metal halide results in a substrate comprising a plurality of halides. In some embodiments, the contacting comprises any one or more contacting methods disclosed herein.

In some embodiments, completing steps 202, 204, and 206 completes one cycle. In some embodiments, completing steps 102, 104, 106, 202, 204, and 206 completes one cycle. In some embodiments, the cycle is restarted by contacting the film obtained in step 206 with a metal halide to obtain a substrate comprising a plurality of halides (step 102). In some embodiments, one or more cycles are performed. In some embodiments, multiple cycles are performed. For example, in some embodiments, at least 1 cycle, at least 5 cycles, at least 10 cycles, at least 50 cycles, at least 100 cycles, at least 500 cycles, or at least 1000 cycles are performed. In some embodiments, 1 to 1000 cycles, or any range or subrange between 1 to 1000 cycles, are performed. In some embodiments, 1 to 900 cycles, 1 to 800 cycles, 1 to 700 cycles, 1 to 600 cycles, 1 to 500 cycles, 1 to 400 cycles, 1 to 300 cycles, 1 to 200 cycles, 1 to 100 cycles, 1 to 50 cycles, 1 to 10 cycles, 10 to 1000 cycles, 50 to 1000 cycles, 100 to 1000 cycles, 200 to 1000 cycles, 300 to 1000 cycles, 400 to 1000 cycles, 500 to 1000 cycles, 600 to 1000 cycles, 700 to 100 cycles, 800 to 1000 cycles, or 900 to 1000 cycles are performed. In some embodiments, the number of cycles performed are determined by the desired thickness of the resulting film.

In some embodiments, the number of cycles performed are sufficient to result in a film having a thickness of 5 Å to 5000 Å, or any range or subrange between 5 Å to 5000 Å. In some embodiments, the film has a thickness of 5 Å to 4500 Å, 5 Å to 4000 Å, 5 Å to 3500 Å, 5 Å to 3000 Å, 5 Å to 2500 Å, 5 Å to 2000 Å, 5 Å to 1500 Å, 5 Å to 1000 Å, 5 Å to 500 Å, 5 Å to 100 Å, 5 Å to 50 Å, 50 Å to 5000 Å, 100 Å to 5000 Å, 500 Å to 5000 Å, 1000 Å to 5000 Å, 1500 Å to 5000 Å, 2000 Å to 5000 Å, 2500 Å to 5000 Å, 3000 Å to 5000 Å, 3000 Å to 5000 Å, 3500 Å to 5000 Å, 4000 Å to 5000 Å, or 4500 Å to 5000 Å.

Some embodiments relate to a kit. In some embodiments, the kit comprises a first container. In some embodiments, the first container comprises a vaporizable precursor. In some embodiments, the vaporizable precursor comprises a metal halide. In some embodiments, the metal halide comprises at least one of an alkali metal halide, an alkaline metal halide, a rare earth metal halide, a transition metal halide, a post-transition metal halide, or any combination thereof. In some embodiments, the metal halide comprises at least one of a scandium halide, a yttrium halide, a lanthanum halide, a zirconium halide, a titanium halide, a hafnium halide, a niobium halide, a tantalum halide, an aluminum halide, a vanadium halide, a molybdenum halide, a tungsten halide, or any combination thereof.

In some embodiments, the kit comprises a second container. In some embodiments, the second container comprises a reducing agent. In some embodiments the reducing agent comprises a compound of the formula:

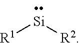

In some embodiments, R¹ and R² independently comprise at least one of an alkyl, an aryl, a cycloalkyl, a heterocycloalkyl, a heteroaryl, an amine, or any combination thereof. In some embodiments, R¹ and R² are bonded to form a cyclic ring. In some embodiments, R¹ and R² are different. In some embodiments, R¹ and R² are the same. In some embodiments, when R¹ and R² are bonded to form a cyclic ring, the number of atoms between R¹ and R² is 1 to 10, or any range or subrange between 1 to 10. In some embodiments, when R¹ and R² are bonded to form a cyclic ring, the number of atoms between R¹ and R² is 1 to 9, 1 to 8, 1 to 7, 1 to 6, 1 to 5, 1 to 4, 1 to 3, 1 to 2, 2 to 10, 3 to 10, 4 to 10, 5 to 10, 6 to 10, 7 to 10, 8 to 10, or 9 to 10. In some embodiments, when R¹ and R² are bonded to form a cyclic ring, the atoms between R¹ and R² comprise at least one of carbon atoms, nitrogen atoms, sulfur atoms, oxygen atoms, phosphorous atoms, or any combination thereof.

In some embodiments, the reducing agent comprises a compound of the formula:

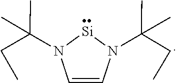

In some embodiments, when the vaporizable precursor and the reducing agent are vaporized and contacted with a substrate, the vaporizable precursor and the reducing agent react to form a film on the substrate. In some embodiments, the film comprises less than 10% by weight of a halide based on a total weight of the film, as disclosed herein. In some embodiments, the film comprises at least one of a metal, a metal silicide, or any combination thereof.

Some embodiments relate to an article. In some embodiments, the article comprises a film. In some embodiments, the film is a reaction product of a reducing agent and a metal halide. In some embodiments, the reducing agent comprises any one or more of the reducing agents disclosed herein. In some embodiments, the metal halide comprises any one or more of the metal halides disclosed herein.

In some embodiments, the film comprises less than 10% by weight of a halide based on a total weight of the film. In some embodiments, the film comprises less than 9%, less than 8%, less than 7%, less than 6%, less than 5%, less than 4%, less than 3%, less than 2%, less than 1%, less than 0.5%, or less than 0.1% by weight of a halide based on the total weight of the film.

In some embodiments, the film comprises 0.01% to 10%, or any range or subrange between 0.01% to 10%, by weight of a halide based on the total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a halide based on a total weight of the film. In some embodiments, the film does not comprise a halide.

In some embodiments, the film comprises at least one of a metal, a plurality of silylenes, or any combination thereof.

In some embodiments, the film comprises at least 90% by weight of at least one of a metal, a plurality of silylenes, or any combination thereof. In some embodiments, the film comprises at least 91%, at least 92%, at least 93%, at least 94%, at least 95%, at least 96%, at least 97%, at least 98%, at least 99%, at least 99.5%, at least 99.9%, at least 99.95%, or at least 99.99% by weight of at least one of a metal, a plurality of silylenes, or a combination thereof, based on the total weight of the film. In some embodiments, the film comprises 100% by weight of at least one of a metal, a plurality of silylenes, or a combination thereof, based on a total weight of the film.

In some embodiments, the film comprises 90% to 99.99%, or any range or subrange between 90% to 99.99%, by weight of at least one of a metal, a plurality of silylenes, or a combination thereof, based on a total weight of the film. In some embodiments, the film comprises 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99% by weight of at least one of a metal, a plurality of silylenes, or a combination thereof, based on a total weight of the film.

In some embodiments, the film comprises less than 10% by weight of a carbon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a carbon based on a total weight of the film. In some embodiment, the film does not comprise a carbon.

In some embodiments, the film comprises 0.01% to 10%, or any range or subrange between 0.01% to 10%, by weight of a carbon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a carbon based on a total weight of the film.

In some embodiments, the film comprises less than 10% by weight of a silicon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a silicon based on a total weight of the film. In some embodiments, the film does not comprise a silicon.

In some embodiments, the film comprises 0.01% to 10%, or any range or subrange between 0.01% to 10%, by weight of a silicon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a silicon based on a total weight of the film.

In some embodiments, the film comprises less than 10% by weight of a nitrogen based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of a nitrogen based on a total weight of the film. In some embodiments, the film does not comprise a nitrogen.

In some embodiments, the film comprises 0.01% to 10%, or any range or subrange between 0.01% to 10%, by weight of a nitrogen based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a nitrogen based on a total weight of the film.

Some embodiments relate to an article. In some embodiments, the article comprises a film. In some embodiments, the film is a reaction product of a silylene and a metal halide. In some embodiments, the metal silylene comprises any one or more of the reducing agents disclosed herein. In some embodiments, the metal halide comprises any one or more of the metal halides disclosed herein.

In some embodiments, the film comprises less than 10% by weight of a halide based on a total weight of the film. In some embodiments, the film comprises less than 9%, less than 8%, less than 7%, less than 6%, less than 5%, less than 4%, less than 3%, less than 2%, less than 1%, less than 0.5%, or less than 0.1% by weight of a halide based on the total weight of the film.

In some embodiments, the film comprises 0.01% to 10%, or any range or subrange between 0.01% to 10%, by weight of a halide based on the total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a halide based on a total weight of the film. In some embodiments, the film does not comprise a halide.

In some embodiments, the film comprises at least one of a metal, a metal silicide, or any combination thereof.

In some embodiments, the film comprises at least 90% by weight of at least one of a metal, a metal silicide, or any combination thereof. In some embodiments, the film comprises at least 91%, at least 92%, at least 93%, at least 94%, at least 95%, at least 96%, at least 97%, at least 98%, at least 99%, at least 99.5%, at least 99.9%, at least 99.95%, or at least 99.99% by weight of at least one of a metal, a metal silicide, or a combination thereof, based on the total weight of the film. In some embodiments, the film comprises 100% by weight of at least one of a metal, a metal silicide, or a combination thereof, based on a total weight of the film.

In some embodiments, the film comprises 90% to 99.99%, or any range or subrange between 90% to 99.99%, by weight of at least one of a metal, a metal silicide, or a combination thereof, based on a total weight of the film. In some embodiments, the film comprises 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99% by weight of at least one of a metal, a metal silicide, or a combination thereof, based on a total weight of the film.

In some embodiments, the film comprises less than 10% by weight of carbon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of carbon based on a total weight of the film. In some embodiment, the film does not comprise carbon.

In some embodiments, the film comprises 0.01% to 10%, or any range or subrange between 0.01% to 10%, by weight of carbon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of carbon based on a total weight of the film.

In some embodiments, the film comprises less than 10% by weight of silicon based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of silicon based on a total weight of the film. In some embodiments, the film does not comprise silicon.

In some embodiments, the film comprises 0.01% to 10%, or any range or subrange between 0.01% to 10%, by weight of silicon based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of silicon based on a total weight of the film.

In some embodiments, the film comprises less than 10% by weight of nitrogen based on a total weight of the film. In some embodiments, the film comprises less than 9%, less than 8%, less than 7%, less than 6%, less than 5%, less than 4%, less than 3%, less than 2%, less than 1%, less than 0.5%, less than 0.1%, or less than 0.05% by weight of nitrogen based on a total weight of the film. In some embodiments, the film does not comprise nitrogen.

In some embodiments, the film comprises 0.01% to 10%, or any range or subrange between 0.01% to 10%, by weight of nitrogen based on a total weight of the film. In some embodiments, the film comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of nitrogen based on a total weight of the film.

Some embodiments relate to a composition. In some embodiments, the composition comprises a reducing agent. In some embodiments, the composition comprises a reducing agent for film deposition. In some embodiments, the composition comprises a reducing agent for film deposition for at least one of a metal, a metal silicide, or any combination thereof. In some embodiments, the reducing agent comprises any one or more of the reducing agents disclosed herein.

Some embodiments relate to a film on a substrate. In some embodiments, the film comprises any film formed according to the methods disclosed herein. In some embodiments, the film comprises any film prepared from any one or more of the precursors disclosed herein.

Any one or more of the embodiments disclosed herein shall be understood to be combinable without departing from the scope or spirit of the disclosure.

### Example 1

A metal halide is vaporized and deposited on a substrate using ALD. A reducing agent comprising the formula:

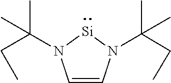

is obtained. The reducing agent is vaporized and deposited on the substrate using ALD. The metal halide and the reducing agent react to form a film on the substrate. The film is a metal film that comprises less than 1% of a halide, less than 1% of a carbon, less than 1% of a silicon, and less than 1% of a nitrogen.

### Example 2

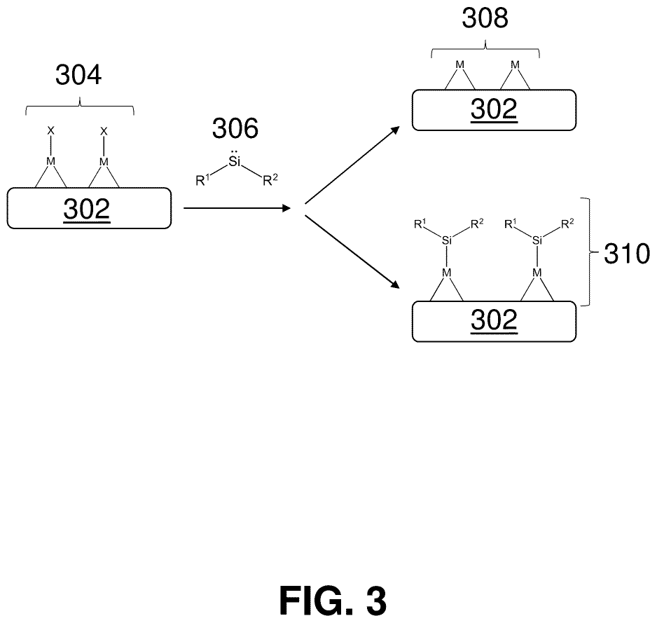

FIG. 3 is an illustration of a method 300 for forming a film, according to Example 2. A metal halide is vaporized and deposited on a substrate 302 using ALD to form a substrate 302 comprising a plurality of halides 304. The plurality of halides 304 is in the form of metal halides. A silylene reducing agent 306 is obtained. The silylene reducing agent 306 is vaporized and deposited on the substrate 302 using ALD. The metal halide and the reducing agent react to form a film on the substrate. The substrate is rinsed to remove any by-products. The film comprises at least one of a metal 308, a plurality of silylenes 310, or any combination thereof.

### Example 3

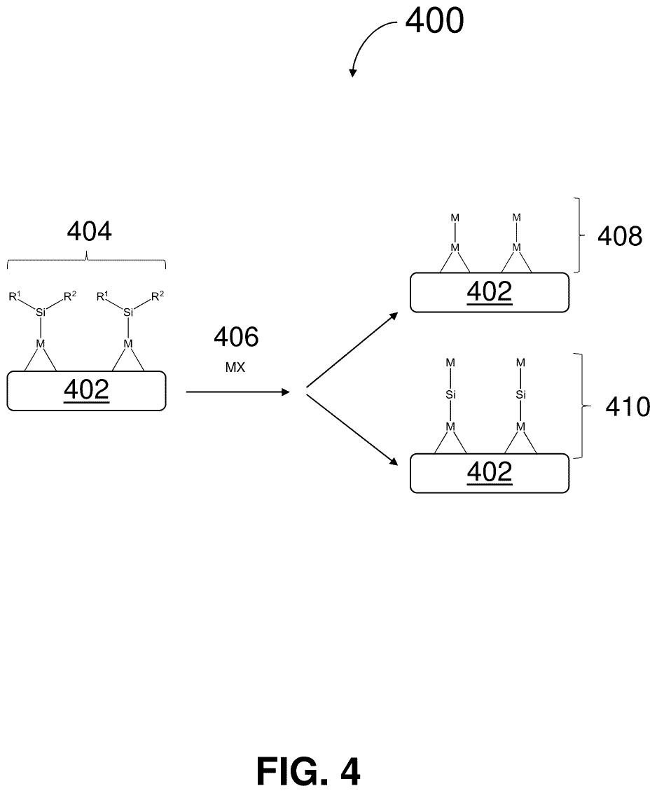

FIG. 4 is an illustration of a method 400 for forming a film, according to Example 3. A substrate 402 comprising a plurality of silylenes 404 is obtained by the method of Example 2. The plurality of silylenes 404 is the form of metal silylenes. A metal halide 406 is vaporized and deposited on the substrate 402 comprising a plurality of silylenes 404 using ALD. The plurality of silylenes 404 and the metal halide 406 react to form a film on the substrate 402. The substrate is rinsed to remove any by-products. The film comprises at least one of a metal 408, a metal silicide 410, or any combination thereof. The film comprises less than 1% of a halide, less than 1% of a carbon, and less than 1% of a nitrogen.

### ASPECTS

Various Aspects are described below. It is to be understood that any one or more of the features recited in the following Aspect(s) can be combined with any one or more other Aspect(s).
Aspect 1. A method comprising:
   obtaining a substrate comprising a plurality of halides;
   obtaining a reducing agent comprising a compound of the formula:

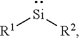

wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring; and
contacting the substrate with the reducing agent to at least remove at least a portion of the plurality of halides.
Aspect 2. The method according to Aspect 1, wherein the obtaining the substrate comprises contacting the substrate with a vaporizable precursor to form the substrate comprising a plurality of halides.
Aspect 3. The method according to any one of Aspects 1-2, wherein the vaporizable precursor comprises a metal halide.
Aspect 4. The method according to any one of Aspects 1-3, wherein the metal halide comprises at least one of a scandium halide, a yttrium halide, a lanthanum halide, a zirconium halide, a titanium halide, a hafnium halide, a niobium halide, a tantalum halide, an aluminum halide, a vanadium halide, a molybdenum halide, a tungsten halide, or any combination thereof.
Aspect 5. The method according to any one of Aspects 1-4, wherein the contacting the substrate with the reducing agent removes at least 90% by weight of the plurality of halides based on a total weight of the plurality of halides.
Aspect 6. The method according to any one of Aspects 1-5, wherein the contacting the substrate with the reducing agent removes 90% to 100% by weight of the plurality of halides based on a total weight of the plurality of halides.
Aspect 7. The method according to any one of Aspects 1-6, wherein the reducing agent comprises the formula:

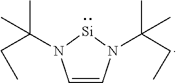

Aspect 8. The method according to any one of Aspects 1-7, wherein the contacting the substrate with the reducing agent results in a film,
   wherein the film comprises less than 10% by weight of a halide based on a total weight of the film.
Aspect 9. The method according to any one of Aspects 1-8, wherein the film comprises at least one of a metal, a plurality of silylenes, or any combination thereof.
Aspect 10. The method according to any one of Aspects 1-9, further comprising contacting the film with a metal halide to obtain a substrate comprising a plurality of halides.
Aspect 11. The method according to any one of Aspects 1-10, wherein the contacting is repeated two or more times to form a film having a thickness of 5 Å to 5000 Å.
Aspect 12. The method according to any one of Aspects 1-11, wherein the film comprises a plurality of silylenes; wherein the method further comprises contacting the film with a metal halide.
Aspect 13. The method according to any one of Aspects 1-12, wherein the contacting the film with a metal halide forms at least one of a metal, a metal silicide, or any combination thereof.
Aspect 14. A method comprising:
   obtaining a substrate comprising a plurality of silylenes;
   obtaining a metal halide;
   contacting the substrate with the metal halide to form a film on the substrate.
Aspect 15. The method according to Aspect 14, wherein the film comprises at least one of a metal, a metal silicide, or any combination thereof.
Aspect 16. The method according to any one of Aspects 14-15, wherein the contacting is repeated two or more times to form a film having a thickness of 5 Å to 5000 Å.
Aspect 17. A kit comprising:
   a first container comprising a vaporizable precursor,
      wherein the vaporizable precursor comprises a metal halide; and
   a second container comprising a reducing agent,
      wherein the reducing agent comprises a compound of the formula:

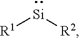

wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring,
wherein, when the vaporizable precursor and the reducing agent are vaporized and contacted with a substrate comprising at least one of a plurality of halides, a plurality of silylenes, or any combination thereof, the vaporizable precursor and the reducing agent react to form a film on the substrate.
Aspect 18. The kit according to Aspect 17, wherein the metal halide comprises at least one of a scandium, a yttrium, a lanthanum, a zirconium, a titanium, a hafnium, a vanadium, a niobium, a tantalum, an aluminum, or any combination thereof.
Aspect 19. The kit according to any one of Aspects 17-19, wherein the reducing agent comprises a compound of the formula:

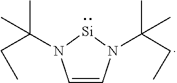

Aspect 20. An article comprising:
   a film,
      wherein the film comprises a reaction product of a reducing agent and a metal halide,
         wherein the reducing agent comprises a compound of the formula:

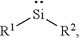

wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring;
wherein the film comprises less than 10% by weight of a halide based on a total weight of the film.
Aspect 21. The article according to Aspect 20, wherein the film comprises at least 90% by weight of at least one of a metal, a plurality of silylenes, or any combination thereof, based on the total weight of the film.
Aspect 22. The article according to any one of Aspects 20-21, wherein the film comprises less than 10% by weight of a carbon based on the total weight of the film.
Aspect 23. The article according to any one of Aspects 20-22, wherein the film comprises less than 10% by weight of a silicon based on the total weight of the film.
Aspect 24. The article according to any one of Aspects 20-23, wherein the film comprises less than 10% by weight of a nitrogen based on the total weight of the film.
Aspect 25. The article according to any one of Aspects 20-24, wherein the metal halide comprises at least one of a scandium, a yttrium, a lanthanum, a zirconium, a titanium, a hafnium, a vanadium, a niobium, a tantalum, an aluminum, or any combination thereof.
Aspect 26. The article according to any one of Aspects 20-25, wherein the reducing agent comprises a compound of the formula:

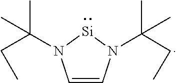

Aspect 27. An article comprising:
   a film,
      wherein the film comprises a reaction product of a metal silylene and a metal halide;
      wherein the film comprises less than 10% by weight of a halide based on a total weight of the film.
Aspect 28. The article according to Aspect 27, wherein the reaction product comprises at least one of a metal, a metal silicide, or any combination thereof.
Aspect 29. A composition comprising:
   a reducing agent for film deposition
      wherein the reducing agent comprises a compound of the formula:

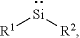

wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring.
Aspect 30. The composition according to Aspect 29, wherein the reducing agent comprises a compound of the formula:

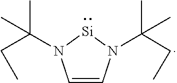

What is claimed is:

1. A method comprising:
obtaining a substrate comprising a plurality of halides;
obtaining a reducing agent comprising a compound of the formula: 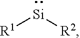
wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring; and
contacting the substrate with the reducing agent to at least remove at least a portion of the plurality of halides.

2. The method of claim 1, wherein the obtaining the substrate comprises contacting the substrate with a vaporizable precursor to form the substrate comprising a plurality of halides.

3. The method of claim 2, wherein the vaporizable precursor comprises a metal halide.

4. The method of claim 3, wherein the metal halide comprises at least one of a scandium halide, a yttrium halide, a lanthanum halide, a zirconium halide, a titanium halide, a hafnium halide, a niobium halide, a tantalum halide, an aluminum halide, a vanadium halide, a molybdenum halide, a tungsten halide, or any combination thereof.

5. The method of claim 1, wherein the contacting the substrate with the reducing agent removes at least 90% by weight of the plurality of halides based on a total weight of the plurality of halides.

6. The method of claim 1, wherein the reducing agent comprises a compound of the formula:

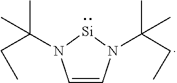

7. The method of claim 1, further comprising contacting the substrate with a metal halide to obtain a substrate comprising a plurality of halides.

8. The method of claim 7, wherein the contacting is repeated two or more times to form a film having a thickness of 1 Å to 5000 Å.

9. The method of claim 1, wherein the contacting the substrate with the reducing agent results in a film,
wherein the film comprises less than 10% by weight of a halide based on a total weight of the film.

10. The method of claim 9, wherein the film comprises at least one of a metal, a plurality of silylenes, or any combination thereof.

11. The method of claim 9, wherein the film comprises a plurality of silylenes; wherein the method further comprises contacting the film with a metal halide.

12. The method of claim 11, wherein the contacting the film with a metal halide forms at least one of a metal, a metal silicide, or any combination thereof.

13. A method comprising:
obtaining a substrate comprising a plurality of silylenes;
obtaining a metal halide; and
contacting the substrate with the metal halide to form a film on the substrate.

14. The method of claim 13, wherein the film comprises at least one of a metal, a metal silicide, or any combination thereof.

15. The method of claim 13, wherein the contacting is repeated two or more times to form a film having a thickness of 5 Å to 5000 Å.

16. A kit comprising:
a first container comprising a vaporizable precursor,
wherein the vaporizable precursor comprises a metal halide; and
a second container comprising a reducing agent,
wherein the reducing agent comprises a compound of the formula: 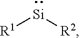
wherein R¹ and R² independently comprise at least one of an alkyl, an aryl, a cycloalkyl, a heterocycloalkyl, a heteroaryl, an amine, or any combination thereof; or
R¹ and R² are bonded to form a cyclic ring,
wherein, when the vaporizable precursor and the reducing agent are vaporized and contacted with a substrate comprising at least one of a plurality of halides, a plurality of silylenes, or any combination thereof, the vaporizable precursor and the reducing agent react to form a film on the substrate.

17. The kit of claim 16, wherein the metal halide comprises at least one of a scandium, a yttrium, a lanthanum, a zirconium, a titanium, a hafnium, a vanadium, a niobium, a tantalum, an aluminum, a molybdenum, a tungsten, or any combination thereof.

18. The kit of claim 16, wherein the reducing agent comprises a compound of the formula:

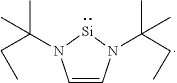

19. A composition comprising:
a reducing agent for film deposition,
wherein the reducing agent comprises a compound of the formula: 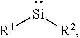
wherein R¹ and R² independently comprise at least one of an alkyl,
an aryl, a cycloalkyl, a heterocycloalkyl, a heteroaryl, an amine, or any combination thereof; or
R¹ and R² are bonded to form a cyclic ring.

20. The composition of claim 19, wherein the reducing agent comprises a compound of the formula: [chemical structure]
